(19) United States
(12) Patent Application Publication
(10) Pub. No.: US 2025/0350289 A1
(43) Pub. Date: Nov. 13, 2025

(54) HIGH SPECTRAL PURITY FREQUENCY QUADRUPLER EMPLOYING BANDPASS FILTER

(71) Applicant: WAVEPIA CO., LTD., Gyeonggi-do (KR)

(72) Inventors: Sang-Hun LEE, Gyeonggi-do (KR); Sang-Yeol LEE, Gyeonggi-do (KR); Sang-Soo KIM, Gyeonggi-do (KR)

(21) Appl. No.: 19/218,463

(22) Filed: May 26, 2025

(30) Foreign Application Priority Data
May 12, 2024 (KR) 10-2024-0107427

(51) Int. Cl. H03L 7/18; H03B 19/14; H03K 5/00

(52) U.S. Cl. CPC H03L 7/18; H03B 19/14; H03K 5/00006

(57) ABSTRACT

A high spectral purity frequency quadrupler employing a bandpass filter, includes a first push-pull doubler that doubles a frequency of an input ultra-high frequency signal, a first bandpass filter that passes a signal having a frequency band twice that of the input ultra-high frequency signal among output signals of the first push-pull doubler, a second push-pull doubler that doubles an ultra-high frequency signal passing through the first bandpass filter, and a second bandpass filter, where the first push-pull doubler comprises a first input impedance matching unit, a first amplifier unit, and a first output impedance matching unit, and where the first input impedance matching unit selectively transmits a second harmonic of the input ultra-high frequency signal to the first amplifier unit, and the first amplifier unit amplifies the second harmonic.

### BACKGROUND

The present disclosure relates to a high spectral purity frequency quadrupler employing a bandpass filter, and more particularly, to a high spectral purity frequency quadrupler employing a bandpass filter that can effectively increase a spectral purity of an input signal while improving a performance of a system by selectively amplifying a second harmonic of the input signal and removing unnecessary harmonics with a bandpass filter.

Recently, an electronic communication system such as 5G mobile communication and phased array antennas requires an ultra-high frequency synthesizer (e.g., PLL) with a wide tuning range and a high spectral purity signal.

CMOS semiconductor technology is utilized to implement the foregoing PLL due to its low cost, low power, and high integration characteristics. However, as the operating frequency increases, CMOS semiconductor technology causes significant difficulties in oscillator design due to its high loss and high phase noise. Therefore, a cascade method of multiplying a frequency using a high-performance low-frequency oscillator is attracting attention as more feasible.

For example, a 28 GHz phased array transceiver uses frequency triples and quadruples after a synthesizer to generate local oscillator signals at 20 to 23 GHZ and 20 GHZ, respectively.

However, conventional frequency multipliers have a problem of generating a lot of unwanted harmonics, which reduces a spectral purity of an input signal and deteriorates a performance of an entire communication system. The background technology of the present disclosure is

published in Korean Patent Publication No. 10-2457443 (published on Oct. 13, 2022).

### SUMMARY OF THE INVENTION

Accordingly, the present disclosure has been made to solve the foregoing problems of the prior art, and the technical problem to be achieved by the present disclosure is to provide a high spectral purity frequency quadrupler employing a bandpass filter that can effectively increase a spectral purity of an input signal while improving a performance of a system by selectively amplifying a second harmonic of the input signal and removing unnecessary harmonics with a bandpass filter.

Technical problems to be solved in the present disclosure are not limited to the above-described problems and other technical problems which are not mentioned will definitely be understood by those skilled in the art from the following description.

In order to achieve the foregoing objectives, there is provided a high spectral purity frequency quadrupler employing a bandpass filter according to one embodiment of the present disclosure, which is a high spectral purity frequency quadrupler employing a bandpass filter including a first push-pull doubler that doubles a frequency of an input ultra-high frequency signal, a first bandpass filter that passes a signal having a frequency band twice that of the input ultra-high frequency signal among output signals of the first push-pull doubler, a second push-pull doubler that doubles an ultra-high frequency signal passing through the first bandpass filter, and a second bandpass filter that passes a signal having a frequency band twice that of the signal passing through the first bandpass filter among output signals of the second push-pull doubler, wherein the first push-pull doubler includes a first input impedance matching unit, a first amplifier unit, and a first output impedance matching unit, and the first input impedance matching unit selectively transmits a second harmonic of the input ultra-high frequency signal to the first amplifier unit, and the first amplifier unit amplifies the second harmonic of the input ultra-high frequency signal to output the amplified second harmonic through the first output impedance matching unit.

Preferably, the first bandpass filter may be configured by connecting an inductor and a capacitor in parallel, and an additional capacitor and an additional switching element may be connected in parallel to the capacitor, and when the additional switching element is turned off, a higher frequency band signal may pass therethrough than when the additional switching element is turned on.

Preferably, the transceiver switch adjusts a magnitude of a transmission reference voltage using a transmission reference digital step attenuator.

Preferably, the second push-pull doubler may include a second input impedance matching unit, a second amplifier unit, and a second output impedance matching unit, wherein the second input impedance matching unit selectively transmits a second harmonic of a signal passing through the first bandpass filter to the second amplifier unit, and the second amplifier unit amplifies the second harmonic of the signal passing through the first bandpass filter to output the amplified second harmonic through the second output impedance matching unit.

Preferably, the second bandpass filter may be configured by connecting an inductor and a capacitor in parallel, and an additional capacitor and an additional switching element may be connected in parallel to the capacitor, and when the additional switching element is turned off, a higher frequency band signal passes therethrough than when the additional switching element may be turned on.

A high spectral purity frequency quadrupler employing a bandpass filter according to embodiments of the present disclosure may effectively increase a spectral purity of an input signal while improving a performance of a system by selectively amplifying a second harmonic of the input signal and removing unnecessary harmonics with a bandpass filter.

### BRIEF DESCRIPTION OF THE DRAWINGS

FIG. 1 is a block diagram of a high spectral purity frequency quadrupler employing a bandpass filter according to one embodiment of the present disclosure.

FIG. 2 is a detailed circuit diagram of a first push-pull doubler in FIG. 1.

FIG. 3 is a detailed circuit diagram of a first bandpass filter in FIG. 1.

FIG. 4 is a half equivalent circuit diagram of the first bandpass filter in FIG. 3.

### DETAILED DESCRIPTION OF THE PREFERRED EMBODIMENT

The detailed description of the present disclosure described below refers to the accompanying drawings, which show, by way of illustration, specific embodiments to carry out the present disclosure. These embodiments are described in sufficient detail to enable those skilled in the art to carry out the present disclosure. It should be understood that various embodiments of the present disclosure are different from one another but are not necessarily mutually exclusive.

For example, it should be understood that specific shapes, structures, and characteristics described herein, in connection with one embodiment, may be implemented in other embodiments without departing from the principles of the present disclosure, and the positions or arrangements of individual elements within each disclosed embodiment may be modified without departing from the principles of the present disclosure.

Therefore, the following detailed description is not to be taken in a limiting sense, and the scope of the present disclosure is defined only by the appended claims along with the entire scope of equivalents thereof, if properly described.

In the drawings, similar reference symbols indicate identical or similar functions across various aspects, and lengths, areas, thicknesses, and shapes thereof may be exaggerated for convenience.

In addition, when a portion may “include” a certain element, unless specified otherwise, it may not be construed to exclude another element but may be construed to further include other elements.

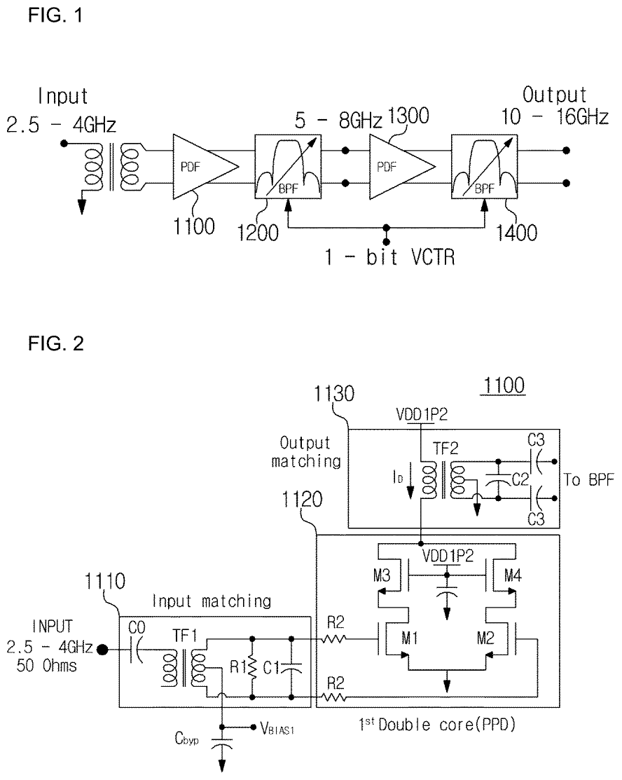

A high spectral purity frequency quadrupler employing a bandpass filter according to one embodiment of the present disclosure, as shown in FIG. 1, includes a first push-pull doubler 1100 that doubles a frequency of an input ultra-high frequency signal (input), a first bandpass filter 1200 that passes a signal having a frequency band twice that of the input ultra-high frequency signal among output signals of the first push-pull doubler 1100, a second push-pull doubler 1300 that doubles an ultra-high frequency signal passing through the first bandpass filter 1200, and a second bandpass filter 1400 that passes a signal having a frequency band twice that of the signal passing through the first bandpass filter 1200 among output signals of the second push-pull doubler 1300.

Here, the first push-pull doubler 1100 includes a first input impedance matching unit 1110, a first amplifier unit 1120, and a first output impedance matching unit 1130, as shown in FIG. 2, wherein the first input impedance matching unit 1110 selectively transmits a second harmonic of the input ultra-high frequency signal to the first amplifier unit 1120, and the first amplifier unit 1120 amplifies the second harmonic of the input ultra-high frequency signal to output the amplified second harmonic through the first output impedance matching unit 1130.

Specifically, the first input impedance matching unit 1110 is configured to include a transformer TF1, capacitors C0, C1, and a resistor R1, as shown in FIG. 2, and the first amplifier unit 1120 is configured to include MOS transistors M1, M2, M3, M4, a capacitor, and resistors R2, and the first output impedance matching unit 1130 is configured to include a transformer TF2 and capacitors C2, C3.

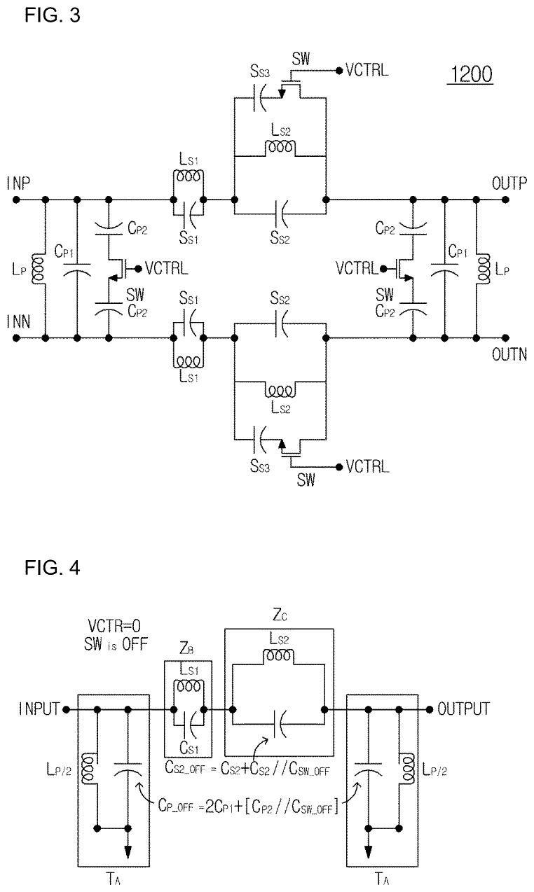

Meanwhile, the first bandpass filter 1200 is configured to connect an inductor Ls2 and a capacitor Ss2 in parallel, as shown in FIGS. 3 and 4, and an additional capacitor Ss3 and an additional switching element SW are connected in parallel to the capacitor Ss2, and when the additional switching element SW is turned off, a higher frequency band signal passes therethrough than when the additional switching element SW is turned on.

In addition, the second push-pull doubler 1300 includes a second input impedance matching unit, a second amplifier unit, and a second output impedance matching unit, wherein the second input impedance matching unit selectively transmits a second harmonic of a signal passing through the first bandpass filter 1200 to the second amplifier unit, and the second amplifier unit amplifies the second harmonic of the signal passing through the first bandpass filter 1200 to output the amplified second harmonic through the second output impedance matching unit.

Here, the second push-pull doubler 1300 may be configured in the same manner as the first push-pull doubler 1100.

Meanwhile, the second bandpass filter 1400 is configured by connecting an inductor and a capacitor in parallel, and an additional capacitor and an additional switching element are connected in parallel to the capacitor, and when the additional switching element is turned off, a higher frequency band signal passes therethrough than when the additional switching element is turned on, and the second bandpass filter 1400 may also be configured in the same manner as the first bandpass filter 1200.

In the above, although the present disclosure has been described and shown with reference to preferred embodiments for illustrating the principles of the present disclosure, the present disclosure is not limited to the exact construction and operation shown and described.

Rather, those skilled in the art will readily appreciate that many changes and modifications to the present disclosure can be made without departing from the concept and scope of the appended claims.

Accordingly, all such appropriate changes, modifications, and equivalents should also be considered to fall within the scope of the present disclosure.

### DESCRIPTION OF REFERENCE NUMERALS

1100: First push-pull doubler
1200: First bandpass filter
1300: Second push-pull doubler
1400: Second bandpass filter
1110: First input impedance matching unit
1120: First amplifier unit
1130: First output impedance matching unit
TF1, TF2: Transformers
C0, C1, C2, C3: Capacitors
R1, R2: Resistors
M1, M2, M3, M4: MOS transistors
Ls2: Inductor
Ss2: Capacitor
Ss3: Additional capacitor
SW: Additional switching element

What is claimed is:

1. A high spectral purity frequency quadrupler employing a bandpass filter, the frequency quadrupler comprising a first push-pull doubler that doubles a frequency of an input ultra-high frequency signal, a first bandpass filter that passes a signal having a frequency band twice that of the input ultra-high frequency signal among output signals of the first push-pull doubler, a second push-pull doubler that doubles an ultra-high frequency signal passing through the first bandpass filter, and a second bandpass filter that passes a signal having a frequency band twice that of the signal passing through the first bandpass filter among output signals of the second push-pull doubler,
wherein the first push-pull doubler comprises a first input impedance matching unit, a first amplifier unit, and a first output impedance matching unit, and
wherein the first input impedance matching unit selectively transmits a second harmonic of the input ultra-high frequency signal to the first amplifier unit, and the first amplifier unit amplifies the second harmonic of the input ultra-high frequency signal to output the amplified second harmonic through the first output impedance matching unit.

2. The frequency quadrupler of claim 1, wherein the first bandpass filter is configured by connecting an inductor and a capacitor in parallel, and an additional capacitor and an additional switching element are connected in parallel to the capacitor, and when the additional switching element is turned off, a higher frequency band signal passes therethrough than when the additional switching element is turned on.

3. The frequency quadrupler of claim 2, wherein the second push-pull doubler comprises a second input impedance matching unit, a second amplifier unit, and a second output impedance matching unit, and
wherein the second input impedance matching unit selectively transmits a second harmonic of a signal passing through the first bandpass filter to the second amplifier unit, and the second amplifier unit amplifies the second harmonic of the signal passing through the first bandpass filter to output the amplified second harmonic through the second output impedance matching unit.

4. The frequency quadrupler of claim 3, wherein the second bandpass filter is configured by connecting an inductor and a capacitor in parallel, and an additional capacitor and an additional switching element are connected in parallel to the capacitor, and when the additional switching element is turned off, a higher frequency band signal passes therethrough than when the additional switching element is turned on.
